(19) United States
(12) Patent Application Publication
(10) Pub. No.: US 2021/0293491 A1
(43) Pub. Date: Sep. 23, 2021

(54) WATER-COOLING HEAT DISSIPATION DEVICE

(71) Applicant: Dongguan Yichen Intelligent Electronics Co., Ltd, Dongguan (CN)

(72) Inventor: Lihua Cai, Jingzhou (CN)

(73) Assignee: Dongguan Yichen Intelligent Electronics Co., Ltd

(21) Appl. No.: 17/341,414

(22) Filed: Jun. 8, 2021

(30) Foreign Application Priority Data
May 29, 2021 (CN) 202121178495.9

(51) Int. Cl. F28D 21/00; F28F 9/02

(52) U.S. Cl. CPC F28D 21/00; F28F 9/02; F28F 2009/0292; F28F 2275/22; F28F 2250/08; F28D 2021/0029

(57) ABSTRACT

The present disclosure provides a water-cooling heat dissipation device, including a liquid guide assembly, a heat exchanger, a heat sink, and a water-cooling pump. The liquid guide assembly includes a first liquid guide pipe, a second liquid guide pipe, and a third liquid guide pipe; two ends of the first liquid guide pipe respectively communicate with the heat exchanger and the heat sink; two ends of the second liquid guide pipe respectively communicate with the heat exchanger and the water-cooling pump; two ends of the third liquid guide pipe respectively communicate with the water-cooling pump and the heat sink; and the water-cooling pump is fixed on the liquid guide assembly.

### TECHNICAL FIELD

The present disclosure relates to the related technical field of heat dissipation devices, in particular, a water-cooling heat dissipation device.

### BACKGROUND

Electronic elements generate heat during operation. In recent years, with the gradual improvement of the performance of a computer system, heat generated by a central processing unit (CPU) and other electronic elements due to operation has also inevitably increased. In order to solve the heat generation problem, a heat dissipation system is usually required to accelerate dissipation of the heat, so as to prevent the electronic elements from being overheated to reduce their lives or from being damaged. Existing heat dissipation systems mainly include an air-cooling heat dissipation system and a water-cooling heat dissipation system. The water-cooling heat dissipation system has been widely used in heat dissipation of the CPU due to its remarkable heat dissipation performance and relatively low noise, and has become one of the important development trends of computer cooling systems.

However, a current water-cooling heat dissipation device on the market has disadvantages such as complex structure, inconvenient installation and maintenance, and high maintenance cost.

### SUMMARY

The present disclosure is directed to provide a water-cooling heat dissipation device that is simple in structure, convenient to install and maintain and low in maintenance cost, so as to overcome the shortcomings in the existing technology.

In order to achieve the above-mentioned purpose, the present disclosure provides the following technical solution: a water-cooling heat dissipation device, including a liquid guide assembly, a heat exchanger, a heat sink, and a water-cooling pump. The liquid guide assembly includes a first liquid guide pipe, a second liquid guide pipe, and a third liquid guide pipe; two ends of the first liquid guide pipe respectively communicate with the heat exchanger and the heat sink; two ends of the second liquid guide pipe respectively communicate with the heat exchanger and the water-cooling pump; two ends of the third liquid guide pipe respectively communicate with the water-cooling pump and the heat sink; and the water-cooling pump is fixed on the liquid guide assembly.

In one of the embodiments, the water-cooling pump includes a shell, and a base, a motor and an impeller which are mounted in the shell; the first liquid guide pipe is arranged in the shell in a penetrating manner; the second liquid guide pipe penetrates through the shell and communicates with the base; the third liquid guide pipe penetrates through the shell and communicates with the base; the motor is arranged at one end of the base; the impeller is arranged in the base; the impeller is connected with the output end of the motor; and the motor is used to drive the impeller to rotate.

In one of the embodiments, the motor is a brushless motor.

In one of the embodiments, the water-cooling pump further includes a first magnetic body and a second magnetic body; the first magnetic body is connected with the output end of the motor; the second magnetic body is nested on the impeller; and the first magnetic body and the second magnetic body are magnetically coupled.

In one of the embodiments, the water-cooling pump further includes a sealing seat; the sealing seat is arranged at an end of the motor close to the base, and the sealing seat is connected with the base through a fastener; the first magnetic body is arranged in the sealing seat; and the sealing seat is used to isolate the motor from external cooling liquid.

In one of the embodiments, the first magnetic body, the second magnetic body, and the impeller are coaxially disposed.

In one of the embodiments, the heat exchanger includes a heat exchange plate and an upper cover; the top of the heat exchange plate is provided with several heat conduction fins at intervals; the upper cover covers an end of the heat exchange plate close to the heat conduction fins; and the first liquid guide pipe and the second liquid guide pipe both communicate with the upper cover.

In one of the embodiments, a sealing pad is arranged between the heat exchange plate and the upper cover.

In one of the embodiments, the heat exchanger further includes a first adapter head and a second adapter head; two ends of the first adapter head respectively communicate with the first liquid guide pipe and the upper cover; and two ends of the second adapter head respectively communicate with the second liquid guide pipe and the upper cover.

In one of the embodiments, the heat sink includes two liquid storage members, a plurality of heat dissipation pipes, and several heat dissipation sheets; the liquid storage members are used to store the cooling liquid; all the heat dissipation pipes are disposed at intervals in a lengthwise direction of the liquid storage members; two ends of all the heat dissipation pipes respectively communicate with the two liquid storage members; and all the heat dissipation sheets are disposed between two adjacent heat dissipation pipes at intervals.

Compared with the prior art, the present disclosure has the beneficial effects as follows:

in the water-cooling heat dissipation device of the present disclosure, the heat exchanger and the water-cooling pump are separately disposed, so that compared with a traditional water-cooling pump and heat exchanger integration design, the present disclosure is lower in maintenance cost and simpler in structure; since the water-cooling pump is an easy-to-damage part, after the water-cooling pump is damaged, only the water-cooling pump is replaced, instead of replacing the water-cooling pump and the heat exchanger as a whole; and in addition, the water-cooling pump is fixed on the liquid guide assembly, so that vibration in a working process of the water-cooling pump can be reduced, thereby reducing the noise and improving the user experience.

### BRIEF DESCRIPTION OF THE DRAWINGS

FIG. 1 is an overall schematic structural diagram of a water-cooling heat dissipation device according to a preferred embodiment of the present disclosure;

FIG. 2 is a structural exploded diagram of a heat exchanger in the water-cooling heat dissipation device shown in FIG. 1;

FIG. 3 is a schematic structural diagram of a heat sink in the water-cooling heat dissipation device shown in FIG. 1;

FIG. 4 is a sectional diagram of a liquid guide assembly and a water-cooling pump in the water-cooling heat dissipation device shown in FIG. 1; and

FIG. 5 is a structural exploded diagram of the water-cooling pump in the water-cooling heat dissipation device shown in FIG. 1.

### REFERENCE SIGNS IN DRAWINGS

100: water-cooling heat dissipation device;

10: liquid guide assembly; 11: first liquid guide pipe; 12: second liquid guide pipe; 13: third liquid guide pipe; 20: heat exchanger; 21: heat exchange plate; 211: heat conduction fin; 22: upper cover; 23: first adapter head; 24: second adapter head; 30: heat sink; 31: liquid storage member; 32: heat dissipation pipe; 33: heat dissipation sheet; 40: water-cooling pump; 41: shell; 42: base; 43: motor; 44: impeller; 45: first magnetic body; 46: second magnetic body; and 47: sealing seat.

### DESCRIPTION OF THE EMBODIMENTS

In order to make the foregoing objectives, features and advantages of the present disclosure more obvious and understandable, the specific implementation modes of the present disclosure are described in detail with reference to the accompanying drawings. Many specific details are described in the following descriptions to facilitate full understanding of the present disclosure. However, the present disclosure can be implemented in a variety of other ways different from those described herein, and those skilled in the art can make similar improvements without departing from the connotation of the present disclosure. Therefore, the present disclosure is not limited by specific embodiments disclosed below.

It should be noted that when an element is referred to as being “fixed” to another element, it can be directly on the other element or an intermediate element may also exist. When an element is considered to be “connected” to another element, it can be directly connected to the other element or an intermediate element may be present at the same time. When the number of one element is said to have “multiple”, it can be any number of two or more. The terms “perpendicular”, “horizontal”, “left”, “right” and similar expressions used herein are for illustrative purposes only, and are not meant to be the only implementation modes.

Unless otherwise defined, all technical and scientific terms used herein are the same as meanings of general understandings of those skilled in the art of the present disclosure. The terms used in the description of the present disclosure herein are merely to describe the specific implementation modes, not intended to limit the present disclosure. The term “and/or” used herein includes any and all combinations of one or more related listed items.

The present utility model is described below in detail in combination with all implementation modes shown in the drawings:

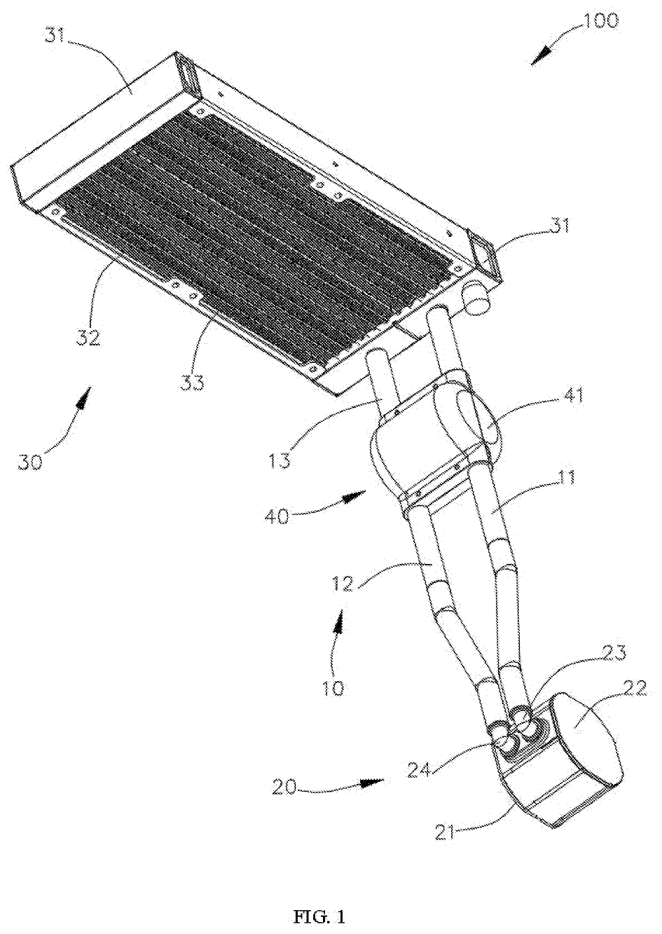

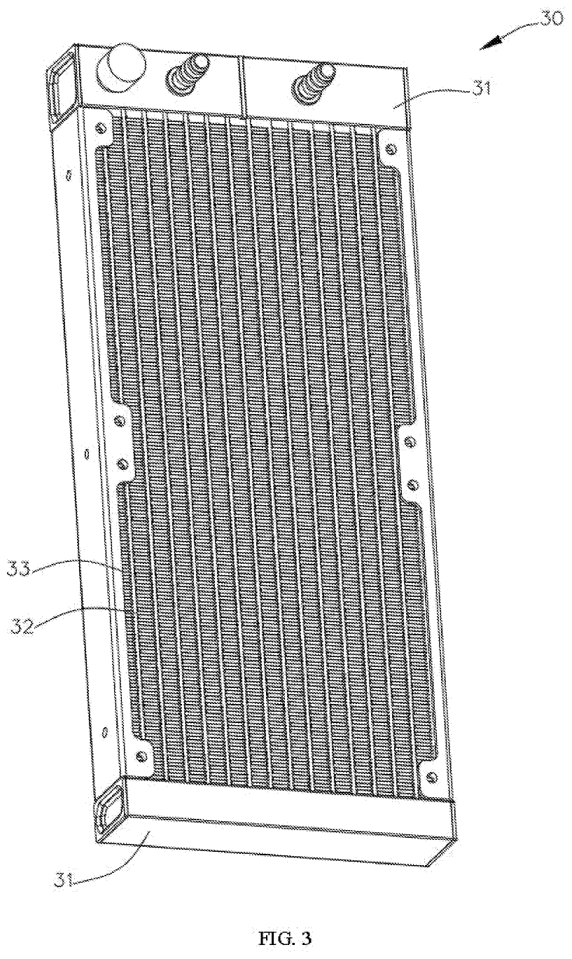

Referring to FIG. 1 to FIG. 5, a water-cooling heat dissipation device 100 of a preferred implementation mode of the present disclosure includes a liquid guide assembly 10, a heat exchanger 20, a heat sink 30, and a water-cooling pump 40. The liquid guide assembly 10 includes a first liquid guide pipe 11, a second liquid guide pipe 12, and a third liquid guide pipe 13; two ends of the first liquid guide pipe 11 respectively communicate with the heat exchanger 20 and the heat sink 30; two ends of the second liquid guide pipe 12 respectively communicate with the heat exchanger 20 and the water-cooling pump 40; two ends of the third liquid guide pipe 13 respectively communicate with the water-cooling pump 40 and the heat sink 30; and the water-cooling pump 40 is fixed on the liquid guide assembly 10. In the water-cooling heat dissipation device 100, the heat exchanger 20 and the water-cooling pump 40 are separately disposed, so that compared with a traditional water-cooling pump 40 and heat exchanger 20 integration design, the present disclosure is lower in maintenance cost and simpler in structure; since the water-cooling pump 40 is an easy-to-damage part, after the water-cooling pump 40 is damaged, only the water-cooling pump 40 is replaced, instead of replacing the water-cooling pump 40 and the heat exchanger 20 as a whole; and in addition, the water-cooling pump 40 is fixed on the liquid guide assembly 10, so that vibration in a working process of the water-cooling pump 40 can be reduced, thereby reducing the noise and improving the user experience.

As shown in FIG. 1, the liquid guide assembly 10 is used for transmit cooling liquid; the liquid guide assembly 10 includes the first liquid guide pipe 11, the second liquid guide pipe 12, and the third liquid guide pipe 13; the two ends of the first liquid guide pipe 11 respectively communicate with the heat exchanger 20 and the heat sink 30; the two ends of the second liquid guide pipe 12 respectively communicate with the heat exchanger 20 and the water-cooling pump 40; and the two ends of the third liquid guide pipe 13 respectively communicate with the water-cooling pump 40 and the heat sink 30.

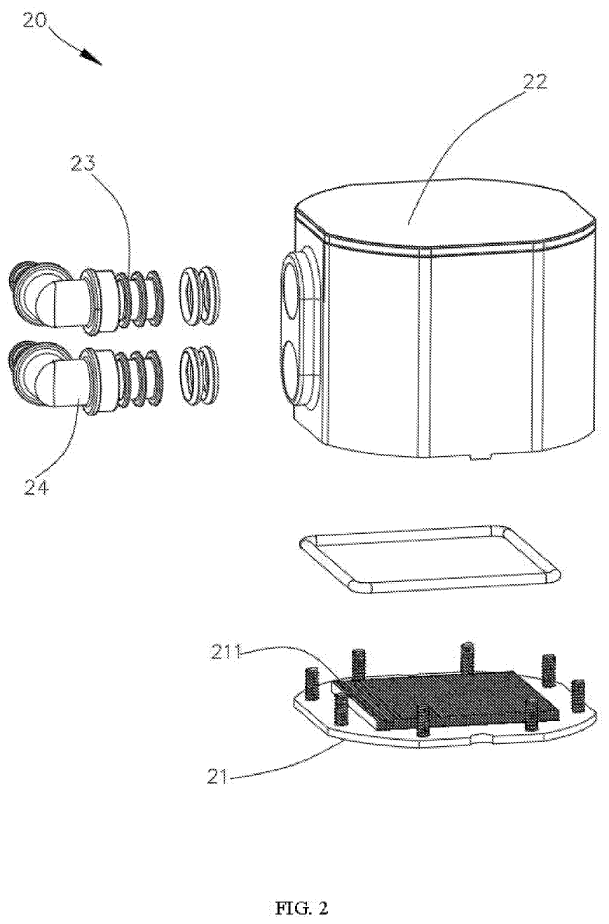

Referring to FIG. 1 and FIG. 2 as well, the heat exchanger 20 is used to transfer and bring, by means of the cooling liquid, away heat generated by a central processing unit (CPU), i.e., to realize cold-heat exchange. The heat exchanger 20 includes a heat exchange plate 21 and an upper cover 22; the top of the heat exchange plate 21 is provided with several heat conduction fins 211 at intervals; and the heat conduction fins 211 can enlarge a contact area of the cooling liquid and the heat exchange plate 21 and improve the heat dissipation efficiency. Optionally, the heat exchange plate 21 is made of a metal with good heat conductivity, such as copper or aluminum. The upper cover 22 covers an end of the heat exchange plate 21 close to the heat conduction fins 211; and the first liquid guide pipe 11 and the second liquid guide pipe 12 both communicate with the upper cover 22; and a cooling passage (not shown) for allowing the cooling liquid to flow is arranged in the upper cover 22. Further, a sealing pad (not marked) is arranged between the heat exchange plate 21 and the upper cover 22. The sealing pad can prevent leakage of the cooling liquid. Further, the heat exchanger 20 further includes a first adapter head 23 and a second adapter head 24; two ends of the first adapter head 23 respectively communicate with the first liquid guide pipe 11 and the upper cover 22; and two ends of the second adapter head 24 respectively communicate with the second liquid guide pipe 12 and the upper cover 22. Further, the first adapter head 23 and the second adapter head 24 are both in threaded connection with the upper cover 22; the end of the first adapter head 23 connected with the upper cover 22 is provided with a sealing ring; the end of the second adapter head 24 connected with the upper cover 22 is provided with a sealing ring (not marked); by the arrangement of the first adapter head 23 and the second adapter head 24, it is convenient for the heat exchanger 20 to be respectively connected with the first liquid guide pipe 11 and the second liquid guide pipe; and the sealing rings can ensure the sealing property to prevent the cooling liquid from leaking to cause a short circuit in an electric element inside a computer host.

As shown in FIG. 2, the heat sink 30 is used to store the cooling liquid and dissipating the heat carried in the cooling liquid to air. The heat sink 30 includes two liquid storage members 31, a plurality of heat dissipation pipes 32, and several heat dissipation sheets 33. The liquid storage members 31 are used to store the cooling liquid. A liquid feeding port (not marked) is formed in one of the liquid storage members 31, so that the cooling liquid can be fed to the heat sink 30 through the liquid feeding port. All the heat dissipation pipes 32 are disposed at intervals in a lengthwise direction of the liquid storage members 31, and two ends of all the heat dissipation pipes 32 respectively communicate with the two liquid storage members 31; and all the heat dissipation sheets 33 are disposed between two adjacent heat dissipation pipes 32 at intervals. The heat dissipation pipes 32 and the heat dissipation sheets 33 can accelerate dissipation of the heat carried in the cooling liquid to the air. Further, a side surface of the heat sink 30 is also provided with a heat dissipation fan (not shown). The heat dissipation fan is used to accelerate the heat dissipation.

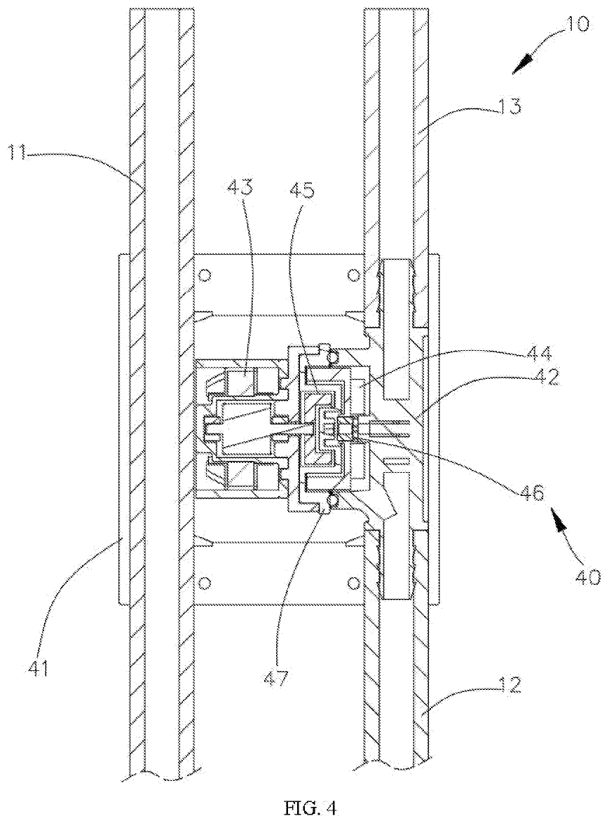

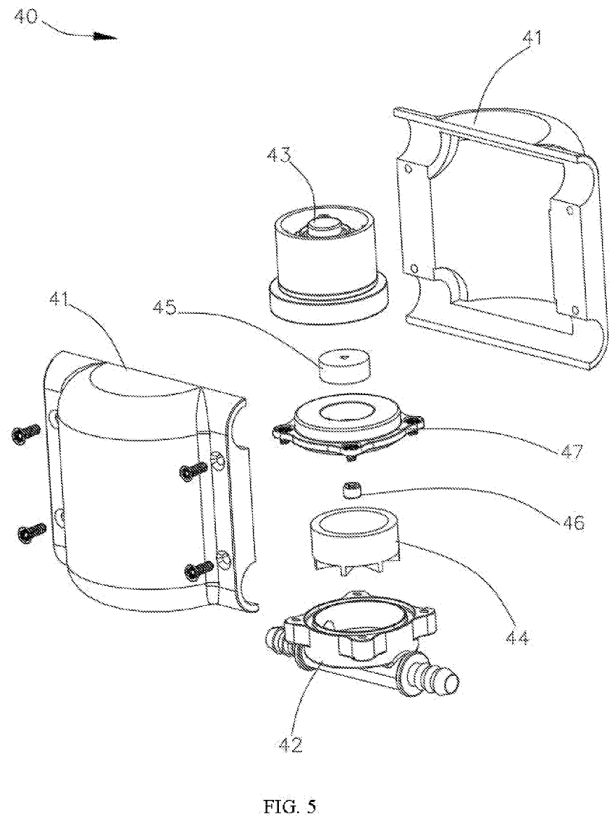

Referring to FIG. 1, FIG. 4 and FIG. 5 together, the water-cooling pump 40 is used to drive the cooling liquid to cyclically flow. The water-cooling pump 40 is fixed on the liquid guide assembly 10. The water-cooling pump 40 includes a shell 41, and a base 42, a motor 43 and an impeller 44 which are mounted in the shell 41. The shell 41 is used to fix the water-cooling pump 40 to the first liquid guide pipe 11, the second liquid guide pipe 12, and the third liquid guide pipe 13. Further, the first liquid guide pipe 11 is arranged in the shell 41 in a penetrating manner; the second liquid guide pipe 12 penetrates through the shell 41 and communicates with the base 42; and the third liquid guide pipe 13 penetrates through the shell 41 and communicates with the base 42. The motor 43 is arranged at one end of the base 42. In the present embodiment, the motor 43 is a brushless motor 43. The impeller 44 is arranged in the base 42; and the impeller 44 is connected with the output end of the motor 43. Further, the water-cooling pump 40 further includes a first magnetic body 45, a second magnetic body 46, and a sealing seat 47. The first magnetic body 45 is connected with the output end of the motor 43; the second magnetic body 46 is nested on the impeller 44; and the first magnetic body 45 and the second magnetic body 46 are magnetically coupled. The sealing seat 47 is arranged at an end of the motor 43 close to the base 42, and the sealing seat 47 is fixedly connected with the base 42 through a screw; the first magnetic body 45 is arranged in the sealing seat 47; the motor 43 drives the first magnetic body 45 to rotate; and under the action of a magnetic field generated by the rotation of the first magnetic body 45, the second magnetic body 46 drives the impeller 44 to rotate, i.e., the motor 43 and the impeller 44 are in no direct contact, but the impeller 44 is driven by magnetic coupling to rotate. In this way, the cooling liquid can be avoided from entering the motor 43, and the anti-short circuit safety of the water-cooling pump 40 is improved. In addition, when the cooling liquid carries a foreign matter, even if the impeller 44 is locked, the motor 43 is not damaged, so that it is safer. In the present embodiment, the first magnetic body 45 and the second magnetic body 46 are both magnets. Further, the impeller 44, the first magnetic body 45, and the second magnetic body 46 are coaxially disposed.

During use, an end of the heat exchange plate 21 away from the heat conduction fins is clung to the top of the CPU and fixed; the heat sink 30 is then fixed on a side surface of a case of the computer host; the cooling liquid is fed to the liquid storage members 31 through the liquid feeding port; after the feeding is completed, the liquid feeding port is covered; and a power line of the water-cooling heat dissipation device 100 is abutted with a corresponding socket on a main board. After a computer is started, the water-cooling pump 40 starts to work; the cooling liquid is conveyed to the heat exchanger 20 from the heat sink 30, and then flows back to the heat sink 30 from the heat exchanger 20, cyclically, to transfer the heat generated by the CPU to the outside.

In the water-cooling heat dissipation device 100 of the present disclosure, the heat exchanger 20 and the water-cooling pump 40 are separately disposed, so that compared with a traditional water-cooling pump 40 and heat exchanger 20 integration design, the present disclosure is lower in maintenance cost and simpler in structure; since the water-cooling pump 40 is an easy-to-damage part, after the water-cooling pump 40 is damaged, only the water-cooling pump 40 is replaced, instead of replacing the water-cooling pump 40 and the heat exchanger 20 as a whole; and in addition, the water-cooling pump 40 is fixed on the liquid guide assembly 10, so that vibration in a working process of the water-cooling pump 40 can be reduced, thereby reducing the noise and improving the user experience.

The technical features of the embodiments described above can be arbitrarily combined. In order to simplify the description, all possible combinations of the technical features in the above embodiments have not been described. However, the combinations of these technical features should be considered as the scope described in this description as long as there is no contradiction in them.

The above-mentioned embodiments only express several implementation modes of the present disclosure, and their descriptions are more specific and detailed, but they cannot be understood as limiting the patent scope of the present disclosure. It should be noted that those of ordinary skill in the art can further make various transformations and improvements without departing from the concept of the present disclosure, and these transformations and improvements all fall within the protection scope of the present disclosure. Therefore, the protection scope of the patent of the present disclosure shall be subject to the appended claims.

What is claimed is:

1. A water-cooling heat dissipation device, comprising a liquid guide assembly, a heat exchanger, a heat sink, and a water-cooling pump, wherein the liquid guide assembly comprises a first liquid guide pipe, a second liquid guide pipe, and a third liquid guide pipe; two ends of the first liquid guide pipe respectively communicate with the heat exchanger and the heat sink; two ends of the second liquid guide pipe respectively communicate with the heat exchanger and the water-cooling pump; two ends of the third liquid guide pipe respectively communicate with the water-cooling pump and the heat sink; and the water-cooling pump is fixed on the liquid guide assembly.

2. The water-cooling heat dissipation device according to claim 1, wherein the water-cooling pump comprises a shell, and a base, a motor and an impeller which are mounted in the shell; the first liquid guide pipe is arranged in the shell in a penetrating manner; the second liquid guide pipe penetrates through the shell and communicates with the base; the third liquid guide pipe penetrates through the shell and communicates with the base; the motor is arranged at one end of the base; the impeller is arranged in the base; the impeller is connected to the output end of the motor; and the motor is used to drive the impeller to rotate.

3. The water-cooling heat dissipation device according to claim 2, wherein the motor is a brushless motor.

4. The water-cooling heat dissipation device according to claim 2, wherein the water-cooling pump further comprises a first magnetic body and a second magnetic body; the first magnetic body is connected with the output end of the motor; the second magnetic body is nested on the impeller; and the first magnetic body and the second magnetic body are magnetically coupled.

5. The water-cooling heat dissipation device according to claim 4, wherein the water-cooling pump further comprises a sealing seat; the sealing seat is arranged at an end of the motor close to the base, and the sealing seat is connected with the base through a fastener; the first magnetic body is arranged in the sealing seat; and the sealing seat is used to isolate the motor from external cooling liquid.

6. The water-cooling heat dissipation device according to claim 4, wherein the first magnetic body, the second magnetic body, and the impeller are coaxially disposed.

7. The water-cooling heat dissipation device according to claim 1, wherein the heat exchanger comprises a heat exchange plate and an upper cover; the top of the heat exchange plate is provided with several heat conduction fins at intervals; the upper cover covers an end of the heat exchange plate close to the heat conduction fins; and the first liquid guide pipe and the second liquid guide pipe both communicate with the upper cover.

8. The water-cooling heat dissipation device according to claim 7, wherein a sealing pad is arranged between the heat exchange plate and the upper cover.

9. The water-cooling heat dissipation device according to claim 7, wherein the heat exchanger further comprises a first adapter head and a second adapter head; two ends of the first adapter head respectively communicate with the first liquid guide pipe and the upper cover; and two ends of the second adapter head respectively communicate with the second liquid guide pipe and the upper cover.

10. The water-cooling heat dissipation device according to claim 1, wherein the heat sink comprises two liquid storage members, a plurality of heat dissipation pipes, and several heat dissipation sheets; the liquid storage members are used to store the cooling liquid; all the heat dissipation pipes are disposed at intervals in a lengthwise direction of the liquid storage members; two ends of all the heat dissipation pipes respectively communicate with the two liquid storage members; and all the heat dissipation sheets are disposed between two adjacent heat dissipation pipes at intervals.
